(19) United States
(12) Patent Application Publication
(10) Pub. No.: US 2010/0259251 A1
(43) Pub. Date: Oct. 14, 2010

(54) ARANGEMENT AND METHOD FOR INFLUENCING AND/OR DETECTING MAGNETIC PARTICLES IN A REGION OF ACTION

(75) Inventor: Hans Marc Bert Boeve, Hechtel-Eksel (BE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/746,607

(22) PCT Filed: Dec. 9, 2008
(86) PCT No.: PCT/IB08/55161

§ 371 Date: Jun. 7, 2010

(30) Foreign Application Priority Data
Dec. 13, 2007 (EP) 07123185.6

(51) Int. Cl. G01R 33/12

(52) U.S. Cl. 324/228

(57) ABSTRACT

An arrangement and a method for influencing and/or detecting magnetic particles in a region of action is disclosed, which arrangement comprises:—selection means (210) for generating a magnetic selection field (211) having a pattern in space of its magnetic field strength such that a first sub-zone (301) having a low magnetic field strength and a second sub-zone (302) having a higher magnetic field strength are formed in the region of action (300),—drive means (220) for changing the position in space of the two sub-zones (301, 302) in the region of action (300) by means of a magnetic drive field (221) so that the magnetization of the magnetic particles (100) changes locally,—receiving means (230) for acquiring signals, which signals depend on the magnetization in the region of action (300), which magnetization is influenced by the change in the position in space of the first and second sub-zone (301, 302),—a control unit (11) for controlling the drive means and/or the selection means and/or the receiving means in such a way that—in a first mode of operation, the position in space of the two sub-zones is changed at a first frequency, and—in a second mode of operation, the position in space of the two sub-zones is changed at a second frequency, the second frequency being at least twice as high as the first frequency.

The present invention relates to an arrangement for influencing and/or detecting magnetic particles in a region of action. Furthermore, the invention relates to a method for influencing and/or detecting magnetic particles in a region of action.

An arrangement and a method of this kind are known from WO 2004/091393 A1. A magnetic field having a spatial distribution of the magnetic field strength is generated such that a first sub-zone having a relatively low magnetic field strength and a second sub-zone having a relatively high magnetic field strength are formed in the examination zone. The position in space of the sub-zones in the examination zone is then shifted, so that the magnetization of the particles in the examination zone changes locally. Signals are recorded which are dependent on the magnetization in the examination zone, which magnetization has been influenced by the shift in the position in space of the sub-zones, and information concerning the spatial distribution of the magnetic particles in the examination zone is extracted from these signals, so that an image of the examination zone can be formed. Such an arrangement and such a method have the advantage that it can be used to examine arbitrary examination objects—e. g. human bodies—in a non-destructive manner and without causing any damage and with a high spatial resolution, both close to the surface and remote from the surface of the examination object. Further, magnetic particles are used to heat a surrounding area, particularly in medical hyperthermia, by variation of the magnetization of magnetic or magnetizable substances. To heat the target region locally, an inhomogeneous magnetic field is generated having a pattern in space of its magnetic field strength such that a first sub-zone having a low magnetic field strength, in which the magnetic particles are not saturated and a second sub-zone having a higher magnetic field strength are generated in the target region. The position in space of the two sub-zones in the target region is then changed for so long that the particles heat up to a desired temperature due to a frequent change in magnetization.

It is an objective of the invention to provide an enhanced apparatus and a more effective method for combined hyperthermia treatment and magnetic particle imaging (MPI).

The above object is achieved by an arrangement for influencing and/or detecting magnetic particles in a region of action which arrangement comprises:
selection means for generating a magnetic selection field having a pattern in space of its magnetic field strength such that a first sub-zone having a low magnetic field strength and a second sub-zone having a higher magnetic field strength are formed in the region of action
drive means for changing the position in space of the two sub-zones in the region of action by means of a magnetic drive field so that the magnetization of the magnetic particles changes locally,
receiving means for acquiring signals, which signals depend on the magnetization in the region of action which magnetization is influenced by the change in the position in space of the first and second sub-zone,
a control unit for controlling the drive means and/or the selection means and/or the receiving means in such a way that
in a first mode of operation, the position of the two sub-zones is changed at a first frequency, and
in a second mode of operation, the position in space of the two sub-zones is changed at a second frequency, the second frequency being at least twice as high as the first frequency.

It is an advantage of the arrangement that in the first mode of operation, the first frequency may be set to a base frequency used for magnetic particle imaging (MPI), which is currently at about 25 kHz in a rather small window, e.g. limited due to the audible frequency range in order to prevent annoyance by noise, in particular for patients. In the second mode of operation, a hyperthermia treatment is advantageously executed more effective at the second frequency, in particular a deliberately higher frequency than the base frequency for MPI scanning. The increased effectiveness advantageously results in a more successful hyperthermia treatment, for example, a bigger size of tumors that can be treated, or a minimized (local) dose of magnetic particles that need to be applied, or a reduced treatment time. A reduction in treatment time prevents, for example, that the immune system of a patient is able to intervene and at least partially remove the magnetic particles from the intended location. Furthermore, MPI is advantageously applicable to provide and focus the heating by hyperthermia treatment locally. The selection field defines a field-free point in which heating will be localised. Moreover the presence of the magnetic particles may advantageously be imaged (monitored) in the first mode of operation before and/or during and/or after the hyperthermia treatment in the second mode of operation. The amplitudes of the required magnetic fields for MPI and hyperthermia treatment are advantageously comparable.

In the arrangement according to the invention, a spatially inhomogeneous magnetic field having a first sub-zone of low magnetic field strength and a second sub-zone of higher magnetic field strength is generated in a region of action in which magnetic particles are situated. By the drive means, the position in space of the two sub-zones can be changed. The generation of the inhomogeneous magnetic field and the change in the position of the sub-zones is known, for example from WO 2004/091393 and is not elaborated in detail. Preferably, in the first mode of operation, the signals from the magnetic particles, which signals are generated by the change in the position in space, are acquired and information on the spatial distribution of the particles is obtained from them. Furthermore preferably, in the second mode of operation, a region for heating-up, which is at least part of the region of action, is heated up by a change in the position in space at the second frequency. It is thus advantageously possible for an object, both to be examined with regard to the spatial distribution of the magnetic particles situated in it (first mode of operation) and for parts of the object to be heated up (second mode of operation). At least part of the various means or components of the arrangement may preferably be used for both modes of operation in this case and thus advantageously only few additional components are required to operate the arrangement in the different modes of operation. Furthermore preferably, the different modes of operation are obtained by virtue of the fact that the control unit controls the existing components differently in the respective cases.

Advantageously, the arrangement allows the magnetic particles to be influenced in one and the same region of action during the different modes of operation without the position in space of the region of action relative to the means or components of the arrangement being changed. In particular, in a first step, the spatial distribution of the magnetic particles in an object may, for example, be determined (in the form of an image, for example) in the first mode of operation. A region for heating-up may advantageously be determined from this information on distribution. In a second step, the region of the object for heating-up that was defined previously, preferably is heated up in the second mode of operation, in which case this heating-up may take place with advantageously high precision in space because the spatial information on the distribution of the magnetic particles that was used in the planning can be used directly for determining the region for heating-up. This is possible because the same components of the arrangement are at least partially used in both steps and there is no need for the object to change its position in relation to the components or to the region of action or region for heating-up.

The field of use of the arrangement according to a preferred embodiment of the invention may advantageously be extended by performing the first and second modes of operation alternately or simultaneously in a third mode of operation. In the third mode of operation, for example, parts of the region of action can be heated up and information on the position in space of the magnetic particles can be obtained at the same time. This is possible because the position in space of the two sub-zones is also changed during the heating-up, as a result of which signals from which information can be obtained on the spatial distribution of the magnetic particles are generated by the magnetic particles, similarly to the first mode of operation.

According to a preferred embodiment of the invention, the drive means comprises at least a first coil arrangement, the first first coil arrangement being supplied with a first current in the first mode of operation and the first coil arrangement being supplied with a second current in the second mode of operation. The second current is preferably an alternate current comprising a respectively higher frequency than the first (AC) current. It is an advantage of this embodiment, that the number of components is limited to a necessary minimum. More preferably, the arrangement comprises a resonant circuit, the resonant circuit being switched on in the second mode of operation to supply the first coil arrangement with the second current.

According to a further preferred embodiment of the invention, the drive means comprises at least a first coil arrangement and a second coil arrangement, the first coil arrangement being supplied with a current in the first mode of operation and the second coil being supplied with a current in the second mode of operation. The skilled artisan will acknowledge, that the first and second frequency of the drive field may thus advantageously be generated by virtue of different AC currents through the first and second coil arrangement.

According to a furthermore preferred embodiment of the invention, the arrangement comprises a switch for switching between the first mode of operation and the second mode of operation, which advantageously allows an operator to quickly change between the operational modes. The control unit, for example, may comprise a physical switch button, or generally any embodiment providing the possibility to switch between the first mode and the second mode, i.e. particularly hardware or software enabled.

According to a furthermore preferred embodiment of the invention, the receiving means comprises a receive coil which in the second mode of operation is used in a feedback mode. Particularly preferable, the receive coil is arranged to assess an effective power that is transmitted to the region of action.

The second frequency, according to the invention, is at least twice as high as the first frequency, i.e. for a typical MPI scanning frequency of 25 kHz as a first frequency, the second frequency is about 50 kHz or higher, preferably in a range between 50 kHz and 1000 kHz. A particularly preferred frequency for hyperthermia would be, for example, at least 100 kHz, most preferably around 400 kHz. In a preferred embodiment, the second frequency is at least four times as high as the first frequency, more preferable about 16 times as high as the first frequency.

The gradient field of the arrangement may, for example, be generated by permanent magnets. An inhomogeneous magnetic field that has a small, first sub-zone of low field strength surrounded by a second sub-zone of greater field strength forms in the region between two poles of the same polarity. Only in those particles that are situated in the zone around the point at which the field strength is zero, i.e. in the first sub-zone, the magnetization is not saturated. In the particles outside this zone the magnetization is in a state of saturation. To make the gradient field switchable or easily adjustable, rather than an arrangement having permanent magnets, in accordance with a furthermore preferred embodiment, the selection means is provided comprising a gradient coil arrangement for generating, a gradient magnetic field in the region of action that reverses its direction and has a zero crossing in the first sub-zone. Advantageously, the properties of this gradient magnetic field are similar to the magnetic field described above. If the gradient coil arrangement comprises, for example, two windings of the same kind which are arranged on the two sides of the target region but through which currents flow in opposite directions (Maxwell coils), then the magnetic field in question is zero at a point along the axis of the windings and the magnetic field strength increases substantially linearly, at opposite polarities, on the two sides of this point.

One possible way of changing the position in space of the two sub-zones is for a coil and/or permanent-magnet arrangement (or parts thereof), to be moved relative to one another. This is particularly preferred if very small objects are being examined with very high gradients (microscopy). By contrast, according to a further preferred embodiment, no mechanical movements are required, as the two sub-zones in the region of action are shifted in position by a temporally variable magnetic field that is superimposed on the gradient magnetic field. If this magnetic field follows a suitable pattern over time and is suitably oriented, the zero point of the field can thus advantageously pass through the region of action in this way. The position in space of the two sub-zones can be changed relatively quickly in this case, which provides additional advantages for the acquisition of signals that depend on the magnetization in the region of action. The variation in magnetization that goes hand in hand with the displacement of the zero point of the field may preferably be detected by the receive coil used for receiving the signals generated in the examination zone. Furthermore preferably, the coil may in this case be a coil that is already being used to generate the magnetic field in the examination zone. There are, however, also advantages in using a separate receive coil for reception, because this coil can be decoupled from the coil arrangement that generates the temporally variable magnetic field and in this way can be optimized in respect of the reception of the signals. Also, an improved signal-to-noise ratio can be obtained with a separate receive coil, but even more so with a plurality of receive coils.

The objective is also achieved by a method for influencing and/or detecting magnetic particles in a region of action, wherein the method comprises the steps of
generating a magnetic selection field having a pattern in space of its magnetic field strength such that a first sub-zone having a low magnetic field strength and a second sub-zone having a higher magnetic field strength are formed in the region of action,
changing the position in space of the two sub-zones in the region of action at a first frequency by means of a magnetic drive field so that the magnetization of magnetic particles in the region of action changes locally,
acquiring signals, which signals depend on the magnetization in the region of action, which magnetization is influenced by the change in the position in space of the first and second sub-zone,
analyzing the signals to obtain information on the spatial distribution of the magnetic particles in the region of action,
defining a region for heating-up that is at least part of the region of action,
changing the position in space of the two sub-zones in the region of action at a second frequency, the second frequency being at least twice as high as the first frequency.

For the local heating-up of the magnetic particles, the position in space of the two sub-zones of the magnetic field is changed continuously. In a similar way to what occurs in the position changing step of the method, this produces signals from which details relating to the spatial distribution of the magnetic particles can be derived. If these signals are acquired such, that the step of acquiring signals and the step of analyzing the signals are performed in addition during the heating-up of the region for heating-up, then information on the spatial distribution can be produced at the same time during the heating-up.

Magnetic particles that are described in DE 102 38 853 may, for example, be used in the arrangement and method.

These and other aspects of the invention are apparent from and will be elucidated with reference to the embodiments described hereinafter.

In the drawings:

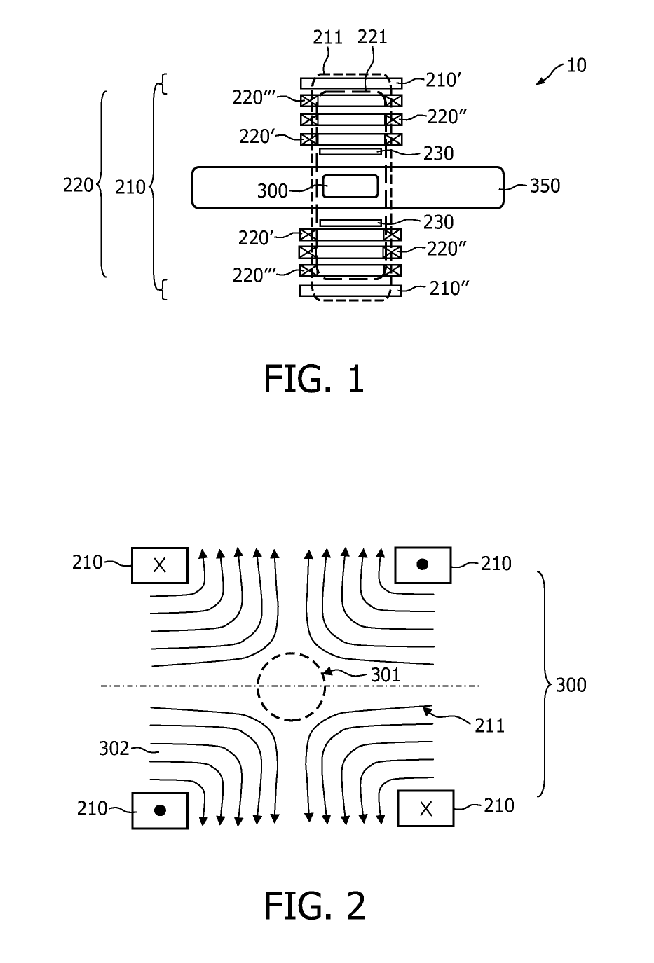

FIG. 1 depicts schematically an embodiment of an arrangement according to the invention.

FIG. 2 shows a pattern of field lines generated by a coil arrangement of the arrangement according to the invention.

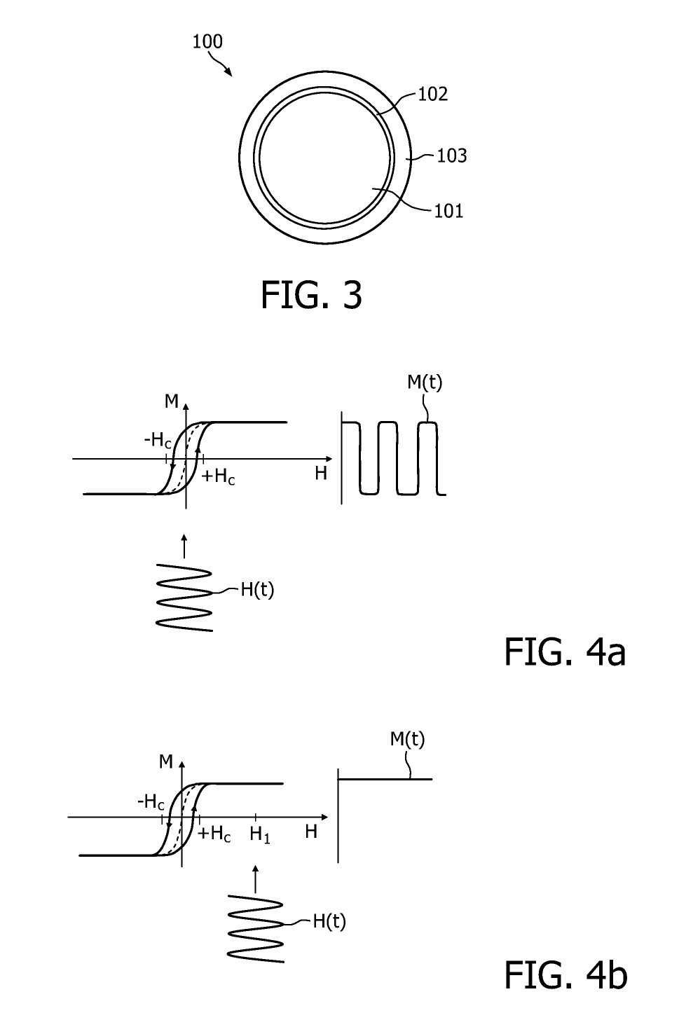

FIG. 3 schematically depicts a magnetic particle present in the region of action.

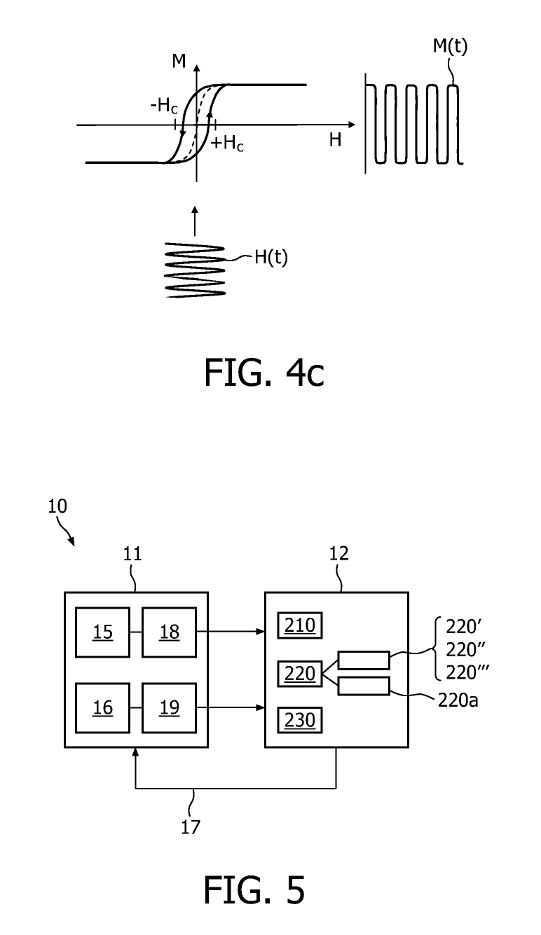

FIGS. 4a, 4b and 4c illustrate the magnetization characteristic of the particle according to FIG. 3.

FIG. 5 illustrates the arrangement and method according to the invention in a block circuit diagram.

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes.

Where an indefinite or definite article is used when referring to a singular noun, e.g. “a”, “an”, “the”, this includes a plural of that noun unless something else is specifically stated.

Furthermore, the terms first, second, third and the like in the description and in the claims are used for distinguishing between similar elements and not necessarily for describing a sequential or chronological order. It is to be understood that the terms so used are interchangeable under appropriate circumstances and that the embodiments of the invention described herein are capable of operation in other sequences than described of illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the present description and claims, should not be interpreted as being restricted to the means listed thereafter; it does not exclude other elements or steps. Thus, the scope of the expression “a device comprising means A and B” should not be limited to devices consisting only of components A and B. It means that with respect to the present invention, the only relevant components of the device are A and B.

In FIG. 1, reference numeral 1 refers to an object for examination or investigation, a patient in this case, who is situated on a patent presentation table of which only part of the plate 2 is indicated. Before an examination of, for example, the gastro-intestinal tract, a liquid or meal containing magnetic particles is administered to the patient 1. The person skilled in the art will recognise that the magnetic particles may as well be injected into the bloodstream or directly into a region of action, depending on the organ or part of the body to be examined.

A respective magnetic particle is illustrated in FIG. 3. It comprises a spherical substrate 100, of glass for example, which is coated with a soft-magnetic layer 101 that is composed of, for example, an iron-nickel alloy (for example, Permalloy). This layer may be covered, for example, by means of a coating layer 102 that protects the particle against acids. The strength of the magnetic field required for the saturation of the magnetization of such particles is dependent on the diameter of the particles. In the case of a diameter of 10 μm, for example, a magnetic field of 1 mT is required for this purpose, whereas in the case of a diameter of 100 μm a magnetic field of 100 mT is required. Smaller values are obtained if a coating of a material having a lower saturation magnetization is chosen. Alternatively, magnetic particles that are referred to as superparamagnetic iron-oxide-based colloids (SPIO's) can be administered to a patient. They are types of magnetic resonance imaging (MRI) contrast agents that consist of nonstoichiometric microcrystalline magnetite cores. The median diameter of such a particle, including its coating, is in the order of 50 nm and more.

FIGS. 4a, 4b and 4c show the magnetization characteristic, that is, the variation of the magnetization M as a function of the field strength H, in a dispersion containing such particles. It can be seen that the magnetization M no longer changes above a field strength of +Hc and below a field strength of −Hc, which means that a saturated magnetization exists. The magnetization is not saturated between the values +Hc and −Hc.

FIG. 4a illustrates the effect of a sinusoidal magnetic field H(t) if no further magnetic field is active. The magnetization reciprocates between its saturation values at the rhythm of a first frequency of the magnetic field H(t) in a first mode of operation. The resultant variation over time of the magnetization is denoted by the reference M(t) in FIG. 4a. It can be seen that the magnetization likewise changes cyclically, by which means a similarly cyclic signal is induced outside the coil. As a result of the non-linearity of the magnetization characteristic, this signal is no longer purely sinusoidal in form but contains harmonics, i.e. higher harmonics of the sinusoidal fundamental wave. These harmonics, which can easily be separated from the fundamental wave, are a measure of the particle concentration.

The dashed part of the line at the center of the curve denotes the approximate mean variation of the magnetization as a function of the field strength. As a deviation from this center line, the magnetization extends slightly to the right when the magnetic field H increases from −Hc to +Hc and slightly to the left when the magnetic field H decreases from +Hc to −Hc. This hysteresis effect may further advantageously be used for the generation of heat. The hysteresis surface area which is formed between the paths of the curve and whose shape and size are dependent on the material, is a measure of the generation of heat upon variation of the magnetization.

In order to increase the heat generation, the magnetic field H(t) is varied at a deliberately higher second frequency in a second mode of operation, which is illustrated in FIG. 4c. The second frequency is at least twice as high as the first frequency. The resultant variation over time of the magnetization is denoted by the reference M(t) in FIG. 4c. A basic assumption of hyperthermia treatment is, that due to local heating a tumor can be treated. Local heating can be realised due to the presence of magnetic nanoparticles in tumor cells or in close vicinity thereof. A minimum heating can lead to apoptosis if the local temperature exceeds 42° C. Using magnetic nanoparticles, the specific power loss is a function of magnetic field frequency and amplitude. Heat generation is a result of two different phenomena. First, a reversal of magnetization inside the magnetic particle and second, rotation of the magnetic particle in a fluid suspension, i.e. relative to its surrounding. Typical values for particle sizes used in hyperthermia experiments is 10-25 nm, i.e. representative for the magnetic core. A preferable second frequency of the magnetic field would be about 400 kHz, with an amplitude of about 10 kA/m. Administration options of magnetic nanoparticles for hyperthermia include the injection of a particle suspension directly into the tumor, or into blood vessels that supply the tumor, and a so-called targeted delivery, either active by labelling with tumor-specific antibodies, or by particle guidance using inhomogeneous magnetic fields.

FIG. 4b shows the effect of a sinusoidal magnetic field H(t) on which a static magnetic field H1 is superposed. Because the magnetization is in the saturated state, it is practically uninfluenced by the sinusoidal magnetic field H(t). The magnetization M(t) remains constant over time at this area. Consequently, the magnetic field H(t) does not cause a change of the state of the magnetization and does not give rise to a detectable signal.

As an example of an embodiment of the present invention, an arrangement 10 is shown in FIG. 2 comprising a plurality of coils forming a selection means 210 whose range defines the region of action 300 which is also called the region of examination 300. For example, the selection means 210 is arranged above and below the object 350. For example, the selection means 210 comprise a first pair of coils 210′, 210″, each comprising two identically constructed windings 210′ and 210″ which are arranged coaxially above and below the patient 350 and which are traversed by equal currents, especially in opposed directions. The first coil pair 210′, 210″ together are called selection means 210 in the following. Preferably, direct currents are used in this case. The selection means 210 generate a magnetic selection field 211 which is in general a gradient magnetic field which is represented in FIG. 2 by the field lines. It has a substantially constant gradient in the direction of the (e.g. vertical) axis of the coil pair of the selection means 210 and reaches the value zero in a point on this axis. Starting from this field-free point (not individually shown in FIG. 2), the field strength of the magnetic selection field 211 increases in all three spatial directions as the distance increases from the field-free point. In a first sub-zone 301 or region 301 which is denoted by a dashed line around the field-free point the field strength is so small that the magnetization of the magnetic particles 100 present in that first sub-zone 301 is not saturated, whereas the magnetization of the magnetic particles 100 present in a second sub-zone 302 (outside the region 301) is in a state of saturation. The field-free point or first sub-zone 301 of the region of action 300 is preferably a spatially coherent area; it may also be a punctiform area or else a line or a flat area. In the second sub-zone 302 (i.e. in the residual part of the region of action 300 outside of the first sub-zone 301) the magnetic field strength is sufficiently strong to keep the magnetic particles 100 in a state of saturation. By changing the position of the two sub-zones 301, 302 within the region of action 300, the (overall) magnetization in the region of action 300 changes. By measuring the magnetization in the region of action 300 or a physical parameter influenced by the magnetization, information about the spatial distribution of the magnetic particles 100 in the region of action can be obtained.

When a further magnetic field—in the following called a magnetic drive field 221 is superposed on the magnetic selection field 210 (or gradient magnetic field 210) in the region of action 300, the first sub-zone 301 is shifted relative to the second sub-zone 302 in the direction of this magnetic drive field 221; the extent of this shift increases as the strength of the magnetic drive field 221 increases. When the superposed magnetic drive field 221 is variable in time, the position of the first sub-zone 301 varies accordingly in time and in space. It is advantageous to receive or to detect signals from the magnetic particles 100 located in the first sub-zone 301 in another frequency band (shifted to higher frequencies) than the frequency band of the magnetic drive field 221 variations. This is possible because frequency components of higher harmonics of the magnetic drive field 221 frequency occur due to a change in magnetization of the magnetic particles 100 in the region of action 300 as a result of the non-linearity of the magnetization characteristics, i.e. the due to saturation effects.

In order to generate the magnetic drive field 221 for any given direction in space, there are provided three drive coil pairs, namely a first drive coil pair 220′, a second drive coil pair 220″ and a third drive coil pair 220′ which together are called drive means 220 in the following. For example, the first drive coil pair 220′ generates a component of the magnetic drive field 221 which extends in a given direction, i.e. for example vertically. To this end the windings of the first drive coil pair 220′ are traversed by equal currents in the same direction. The two drive coil pairs 220″, 220″' are provided in order to generate components of the magnetic drive field 221 which extend in a different direction in space, e.g. horizontally in the longitudinal direction of the region of action 300 (or the patient 350) and in a direction perpendicular thereto. If second and third drive coil pairs 220″, 220′″ of the Helmholtz type were used for this purpose, these drive coil pairs would have to be arranged to the left and the right of the region of treatment or in front of and behind this region, respectively. This would affect the accessibility of the region of action 300 or the region of treatment 300. Therefore, the second and/or third magnetic drive coil pairs or coils 220″, 220′″ are also arranged above and below the region of action 300 and, therefore, their winding configuration must be different from that of the first drive coil pair 220′. Coils of this kind, however, are known from the field of magnetic resonance apparatus with open magnets (open MRI) in which a radio frequency (RF) drive coil pair is situated above and below the region of treatment, said RF drive coil pair being capable of generating a horizontal, temporally variable magnetic field. Therefore, the construction of such coils need not be further elaborated herein.

The arrangement 10 according to the present invention further comprise receiving means 230 that are only schematically shown in FIG. 1. The receiving means 230 usually comprise coils that are able to detect the signals induced by the magnetization pattern of the magnetic particle 100 in the region of action 300. Coils of this kind, however, are known from the field of magnetic resonance apparatus in which e.g. a radio frequency (RF) coil pair is situated around the region of action 300 in order to have a signal to noise ratio as high as possible. Therefore, the construction of such coils need not be further elaborated herein.

In FIG. 5, a block circuit diagram illustrates the arrangement 10 and method according to the invention. A control unit 11 may cooperate with a workstation (not shown) that is provided with a monitor for showing images representing the distribution of the particles in the region of action. Inputs can be made by a user via a keyboard or some other input unit. The control unit 11 comprises a first circuitry 15 for a first mode of operation and a second circuitry 16 for a second mode of operation. A scanner 12 comprises selection means 210 for generating the magnetic selection field having a pattern in space of its magnetic field strength such that the first sub-zone 301 and the second sub-zone 302 (FIG. 2) are formed in the region of action, drive means 220 for changing the position in space of the two sub-zones 301, 302 in the region of action by means of a magnetic drive field and receiving means 230 for acquiring signals, which signals depend on the magnetization in the region of action. The acquired signal is returned via a feedback 17 to the control unit 11.

The selection means 210 and the drive means 220 may receive their currents from current amplifiers (not shown). The waveforms over time of the currents to be amplified, which currents generate the desired magnetic fields, are preset by a waveform generator 18 in the first mode of operation and by a second waveform generator 19 in the second mode of operation. The first and second waveform generators 18, 19 are controlled by the first or second circuitry 15, 16 respectively, which calculate the waveform over time required for the particular examination, investigation or treatment procedure. The second frequency of the magnetic drive field generated by the drive means 220 in the second mode of operation is at least twice as high as the first frequency in the first mode of operation. In the first mode of operation, the arrangement 10 is advantageously adapted for magnetic particle imaging (MPI), whereas in the second mode, hyperthermia treatment may be applied.

According to the invention, hyperthermia treatment is advantageously combined with MPI. MPI is advantageously suitable to provide and focus heating locally, i.e. by design of a static background field, i.e the selection field that defines the field-free point in which heating will be localised. Moreover, the presence of the particles can be imaged (monitored) before and/or during and/or after the heating experiment. The amplitudes of the required magnetic fields for MPI and hyperthermia treatment are comparable. Whereas MPI inherently reflects a volumetric, 3D approach to create a field free point, any additional hyperthermia treatment can be limited to only one dimension, e.g. by addition or re-use of any particular coil set dedicated to hyperthermia treatment.

The arrangement is preferably equipped with a switch (not shown) to change between the first and second mode of operation. In the second mode of operation, the hyperthermia treatment is executed at a considerably higher second frequency compared to the first frequency used for MPI in the first mode of operation. For this purpose, the drive means 220 preferably comprises at least a first coil arrangement 220′, 220″, 220′″ for the first operational mode and a second coil arrangement 220a for the second mode. Alternatively preferable, an additional current may be sent through the single first coil arrangement 220′, 220″, 220′″ of the drive means 220. A dedicated resonant circuit (not shown) is preferably added to power the coil in which the additional (ac) magnetic field is created for hyperthermia treatment. A receive coil of the receiving means 230 may advantageously be used in a feedback mode in the second mode of operation, e.g. to assess the effective power that is transmitted during treatment, based on the local concentration of magnetic particles that has been defined a priori during MPI imaging.

In a preferred third mode of operation, regions selected for heating-up are heated up exactly as in the second mode of operation. Images of the region of action are provided at the same time. This is possible, as the first sub-zone 301 is shifted as well during the heating-up, and as a result, as in the first mode of operation, signals are generated from which images of the region of action can be reconstructed and shown. Signals and/or images may advantageously be interpreted on-line to adapt the hyperthermia treatment for any temporal variations in the local concentration of magnetic particles in the region of action, e.g. due to pharmacokinetic effects.

1. An arrangement (10) for influencing and/or detecting magnetic particles (100) in a region of action (300), which arrangement comprises:
selection means (210) for generating a magnetic selection field (211) having a pattern in space of its magnetic field strength such that a first sub-zone (301) having a low magnetic field strength and a second sub-zone (302) having a higher magnetic field strength are formed in the region of action (300),
drive means (220) for changing the position in space of the two sub-zones (301, 302) in the region of action (300) by means of a magnetic drive field (221) so that the magnetization of the magnetic particles (100) changes locally,
receiving means (230) for acquiring signals, which signals depend on the magnetization in the region of action (300), which magnetization is influenced by the change in the position in space of the first and second sub-zone (301, 302),
a control unit (11) for controlling the drive means and/or the selection means and/or the receiving means in such a way that
in a first mode of operation, the position in space of the two sub-zones is changed at a first frequency, and
in a second mode of operation, the position in space of the two sub-zones is changed at a second frequency, the second frequency being at least twice as high as the first frequency.

2. Arrangement according to claim 1, wherein the drive means (220) comprises at least a first coil arrangement (220′, 220″, 220′″), the first first coil arrangement being supplied with a first current in the first mode of operation and the first coil arrangement being supplied with a second current in the second mode of operation.

3. Arrangement according to claim 2, further comprising a resonant circuit, the resonant circuit being switched on in the second mode of operation to supply the first coil arrangement (220′, 220″, 220′″) with the second current.

4. Arrangement according to claim 1, wherein the drive means (220) comprises at least a first coil arrangement (220′, 220″, 220′″) and a second coil arrangement (220a), the first coil arrangement being supplied with a current in the first mode of operation and the second coil arrangement being supplied with a current in the second mode of operation.

5. Arrangement according to claim 1, further comprising a switch for switching between the first mode of operation and the second mode of operation.

6. Arrangement according to claim 1, wherein the receiving means (230) comprises a receive coil which in the second mode of operation is used in a feedback mode.

7. Arrangement according to claim 6, wherein the receive coil is arranged to assess an effective power that is transmitted to the region of action.

8. Arrangement according to claim 1, wherein the second frequency is at least four times as high as the first frequency, preferably about 16 times as high as the first frequency.

9. Arrangement as claimed in claim 1, wherein the selection means (210) comprise a gradient coil arrangement (210′, 210″) for generating a gradient magnetic field that reverses its direction and has a zero crossing in the first sub-zone.

10. Arrangement according to claim 1, wherein the two sub-zones (301, 302) in the region of action (300) are shifted in position by a temporally variable magnetic field that is superimposed on the gradient magnetic field.

11. A method for influencing and/or detecting magnetic particles (100) in a region of action (300), wherein the method comprises the steps of
generating a magnetic selection field (211) having a pattern in space of its magnetic field strength such that a first sub-zone (301) having a low magnetic field strength and a second sub-zone (302) having a higher magnetic field strength are formed in the region of action (300),
changing the position in space of the two sub-zones (301, 302) in the region of action (300) at a first frequency by means of a magnetic drive field (221) so that the magnetization of magnetic particles (100) in the region of action (300) changes locally,
acquiring signals, which signals depend on the magnetization in the region of action (300), which magnetization is influenced by the change in the position in space of the first and second sub-zone (301, 302),
analyzing the signals to obtain information on the spatial distribution of the magnetic particles in the region of action,
defining a region for heating-up that is at least part of the region of action,
changing the position in space of the two sub-zones in the region of action at a second frequency, the second frequency being at least twice as high as the first frequency.
